(19) United States
(12) Patent Application Publication
(10) Pub. No.: US 2008/0093692 A1
(43) Pub. Date: Apr. 24, 2008

(54) Audio Processing Device with Encapsulated Electronic Component

(75) Inventors: Frank E. Rasmussen, Smorum (DK); Jorgen Skindhoj, Smorum (DK); Anders E. Petersen, Smorum (DK)

Correspondence Address: DYKEMA GOSSETT PLLC, FRANKLIN SQUARE, THIRD FLOOR WEST, 1300 I STREET, NW, WASHINGTON, DC, 20005, US

(73) Assignee: OTICON A/S

(21) Appl. No.: 11/661,935

(22) PCT Filed: Sep. 5, 2005
(86) PCT No.: PCT/EP05/54355

§ 371 Date: Mar. 27, 2007

(30) Foreign Application Priority Data
Sep. 13, 2004 (DK) PA 2004 01385

(51) Int. Cl. H01L 29/84; H01L 21/56

(52) U.S. Cl. 257/416; 438/51; 257/E29.324; 257/E21.502

(57) ABSTRACT

The invention regards an audio processing device with at least one encapsulated electronic component mounted and electrically connected to electric leads in a mounting substrate. Further electric components are mounted for connection with the encapsulated electronic component through the substrate and the encapsulation material is moulded onto the substrate. According to the invention at least one metal layer is deposited on a surface part of the encapsulation material. The invention further regards a method for producing an amplifier for an audio device whereby at least one encapsulated electronic component is mounted on, and electrically connected to a PCB and where the encapsulation material is provided to protect the electronic component wherein further a metal layer is generated at least on a surface area of the encapsulation material.

### AREA OF THE INVENTION

The invention concerns an audio processing device with an electronic component such as a chip, which has been encapsulated. Such an encapsulation is common and serves the purpose of protecting sensitive components against light and other environmental exposures. The encapsulation is usually achieved in an injection moulding process, wherein the chip and PCB substrate is enclosed in a mould and the encapsulation material is injected into the mould cavity around the electronic component and caused to solidify in the closed mould, where after the electronic component with the solid encapsulation material is removed from the mould cavity. Other ways of moulding the encapsulation are known, such as dispensing material onto and around the electronic component, and subsequently solidifying the material.

### BACKGROUND OF THE INVENTION

In audio devices such as hearing aids and headsets where small size is very important, it is desirable that the PCB remains as small as possible. Also the encapsulation should take up as little volume as possible. Further mounting area for further electronic parts like capacitors, contacts and antennas should remain as small as possible in order to minimize the volume of the PCB.

### SUMMARY OF THE INVENTION

The invention provides an audio device with at least one encapsulated electronic component. The encapsulated component is mounted and electrically connected to a substrate and further electric components are mounted for connection with the encapsulated component through the substrate. The encapsulated component is protected by an encapsulation material moulded onto the substrate. According to the invention at least one metal layer is deposited on a surface part of the encapsulation material. The metal layer provides a very dense and effective light protection, and as such may allow a very thin layer of encapsulation material to be used. The encapsulated component, possibly a chip may be accompanied by one or several other electric components, all of which are embedded in the encapsulation material.

In a further embodiment the metal layer on the encapsulation material is provided as conductive metal traces and electric components are formed onto or mounted onto the surface of the encapsulation such that the components are connected with the leads in the substrate through the metal traces. By having electric components on the surface of the encapsulation material more space becomes available for mounting purposes as components like capacitors and resistors are mountable on top of the chip and the metal traces will provide the connection between the components and the PCB.

In a further embodiment the metal layers or traces form capacitors, coils, antennas or other active or passive devices on the encapsulation material. This allows such components to be generated in a very space saving manner.

In a further embodiment the encapsulation material comprise cavities or other surface structures, serving as part of, or receiving elements for individual components. Such surface structures are provided simply by providing mirror images thereof in the mould used for the moulding of the encapsulation. The provision of metal traces can be caused to follow possible cavities or raised areas on the surface of the material. The individual component mounted in or on cavities or other surface structures may comprise microphone or receiver parts or other transducer elements.

The invention further comprise a method for producing an amplifier for an audio device whereby an electronic component is mounted on and electrically connected to a PCB and where an encapsulation material is provided to protect the electronic component wherein further a metal layer is generated at least on a surface area of the encapsulation material. Preferably the encapsulated component comprises a semiconductor chip.

In an embodiment of the method the metal layer is deposited by an electrochemical deposition method. Such methods are known in connection with MID techniques developed in recent years. Here, the surface material of the encapsulation must have special properties, which allows the deposition of a metal layer. This is achieved by the addition to the encapsulation material of a compound comprising an organic metal complex which is activated in the areas where the metal is to be deposited. The activation step may be performed by treatment with laser light, and this allows electrically conductive, thin traces to be deposited on the surface. The compound comprising the organic metal complex can be provided as part of the encapsulation material in only the areas wherein the metal is to be deposited. Here a two component moulding technique could be used.

In a further embodiment of the method according to the invention, the metal layer is deposited through a nozzle directly onto the surface of the chip encapsulation material. In this procedure an aerosol stream is focused, deposited, and patterned onto the surface of the encapsulation material. The surface need not be planar to perform this process. After deposition of the material thermal annealing or photochemical annealing using laser decomposition is performed in order to achieve physical and/or electrical properties near that of the bulk material.

Other ways to deposit metal layers on top of the encapsulation material may be used according to the invention. The entire surface may be electroplated and later the metal may be stripped off by burning in the areas where no metal is desired.

### BRIEF DESCRIPTION OF THE DRAWINGS

FIG. 1 is a side view of an audio device according to the invention,

FIG. 2 shows an embodiment corresponding to FIG. 1, but were a component is mounted underneath the microphone membrane,

FIG. 3 shows an example of the invention where a push button is provided on top of the chip,

FIG. 4 is an embodiment, wherein a reed switch is mounted partially embedded in a cavity over the chip,

FIG. 5 is an embodiment whereby the chip encapsulation is entirely coated with a metal layer for protection against light and electromagnetic radiation,

FIG. 6 displays the possibility of providing a coil on top of the chip using metal traces,

FIG. 7 is a perspective view of part of a PCB with rows of IC-devices mounted thereon,

FIG. 8 shows the PCB of FIG. 7, but now with the encapsulation material moulded onto the PCB,

FIG. 9 a perspective view of leads formed onto the chip encapsulation and the PCB,

FIG. 10 is the device shown in FIG. 9, but now with components mounted onto top of the chip encapsulation.

### DESCRIPTION OF A PREFERRED EMBODIMENT

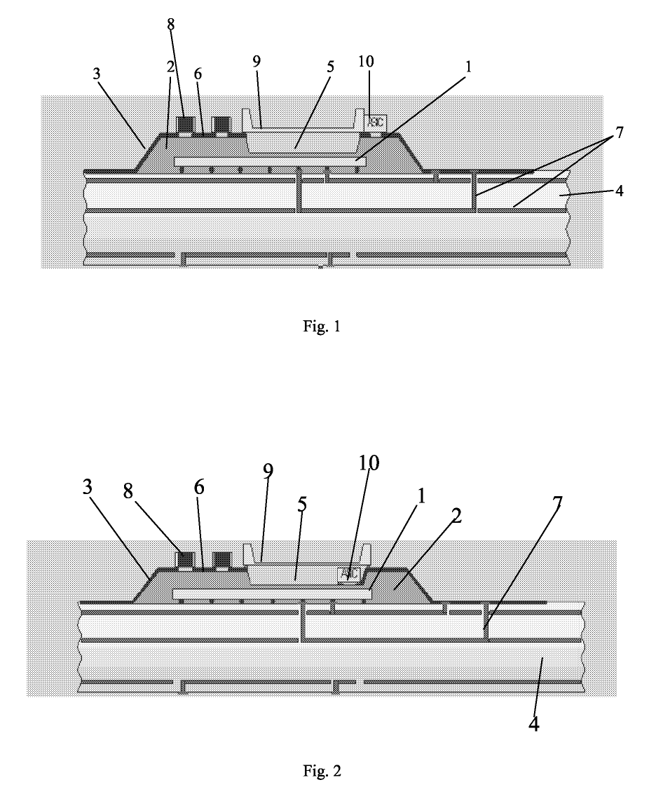

FIG. 1 shows a part of a hearing aid amplifier with a chip 1 which is covered by an encapsulation material 2. On top of the encapsulation material 2 a metal layer 3 is provided. In this case the chip is mounted by traditional flip chip technology on a flexible PCB 4. Any other PCB may however be used. The encapsulation is provided by means of transfer moulding. As can be seen in FIG. 1 a cavity 5 is created in the upper part of the encapsulation material 2. The transfer moulded encapsulation 2 is metallized on parts of the surface to create a redistribution circuitry 6. The redistribution circuitry 6 on the chip encapsulation 2 is preferably connected to the chip 1 via metal lines 7 embedded in and on the flex print 4. In the displayed embodiment a chip is being encapsulated, but other components could be encapsulated according to the invention.

After metallization, components 8,9,10 are mounted followed by reflow soldering. In this case the remaining components are SMD's 8 and a membrane chip 9. The membrane chip 9 constitutes part of a microphone such that when it is added on top of the cavity 5 a silicon microphone is created. Further an ASIC 10 for preamplification and signal processing is shown in FIG. 1 as a possible component mounted on top of the chip encapsulation.

In FIG. 2 basically the same structure is displayed. Here however the preamplifier 10 is placed in the cavity 5. This will assure some protection of the delicate ASIC 10 circuitry and further it will allow other components to be mounted onto the limited available area.

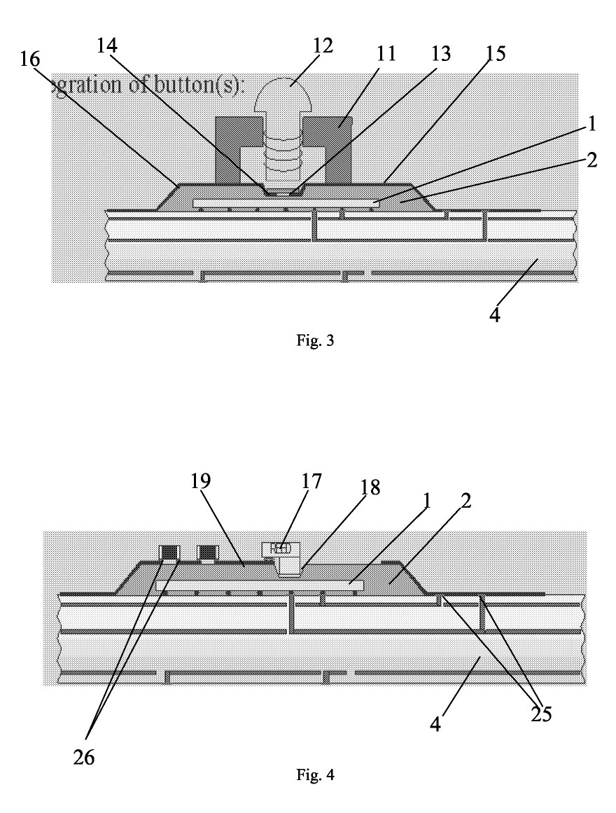

In FIG. 3, the area on top of the chip 1 is used for a push button. The button comprises a housing 11 and an actuator part 12. When the actuator 12 is depressed an electric connection is created between two contact points 13, 14 on top of the encapsulation material 2. Two leads 15, 16 connects the contact points 13, 14 with the circuitry and the chip 1.

FIG. 4 displays a further embodiment of the invention. Here a small reed switch 17 is arranged on top of the encapsulation material 2. A cavity 18 is provided for a protruding part of the reed switch to assure that the switch uses only a minimum of space and is mechanically stabilized. Electric leads 19 connects the reed switch with the circuitry and the chip 1.

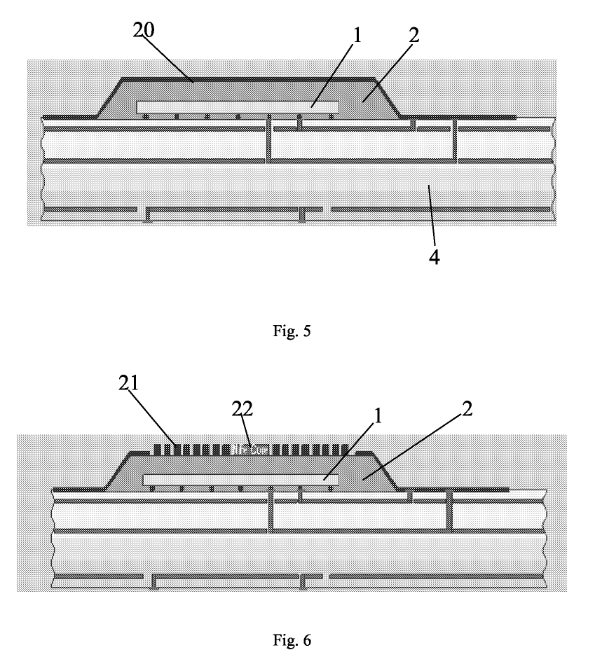

The embodiment in FIG. 5 shows another possibility which may be employed with the use of the invention. Here the surface of the encapsulation material 2 is not only metallized in certain areas or along traces but a metal layer 20 is applied to the complete encapsulation. This will help to protect the chip 1 against electromagnetic noise which could otherwise affect the delicate circuitry and cause noise. And further such a layer allows the layer of encapsulation material on top of the chip to be thin without compromising the light protection.

FIG. 6 displays yet another embodiment of the invention. Here a component is generated by the shape of the metallic traces 21 on top of the chip encapsulation. This could be a coil as displayed in the example. Such a coil may be used for receiving or radiating electromagnetic energy and thus be used in a wireless transmission system. The coil which is displayed further has a metal core 22. Antennas of other shapes could be made with metal traces on top of the chip in this manner.

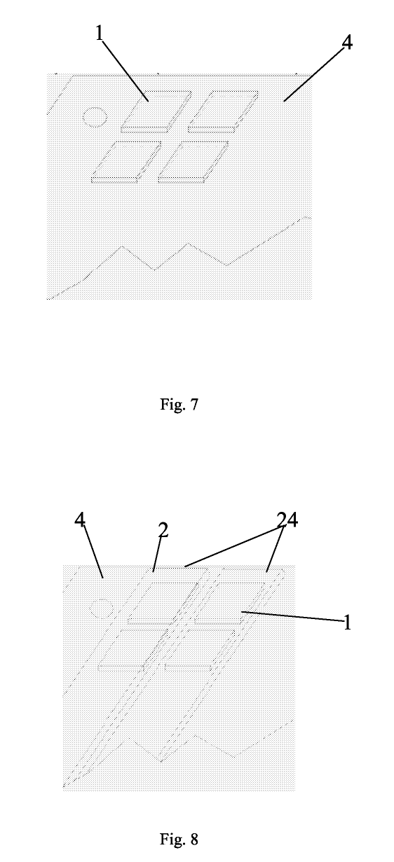

In FIGS. 7, 8, 9 and 10 the process for generating the audio processing device is exemplified. In FIG. 7 a part of a PCB board 4 with the IC devices 1 is shown. The IC's 1 are in electric contact with the circuitry of the PCB 4 through wire bonding or by solder bump bonding or other connecting means known in the art. As seen the IC silicon devices 1 are mounted in rows. In FIG. 8 it is shown how each row of IC's becomes over-moulded with the encapsulation material 2. This is done by placing the entire board 4 in a mould which has a cavity 24 for each row of IC's and then filling out the cavity 24 with liquid encapsulation material 2. The material is then caused to solidify whereafter the PCB 4 is removed from the mould. The mould may comprise surface structures over or near the silicon IC devices 1.

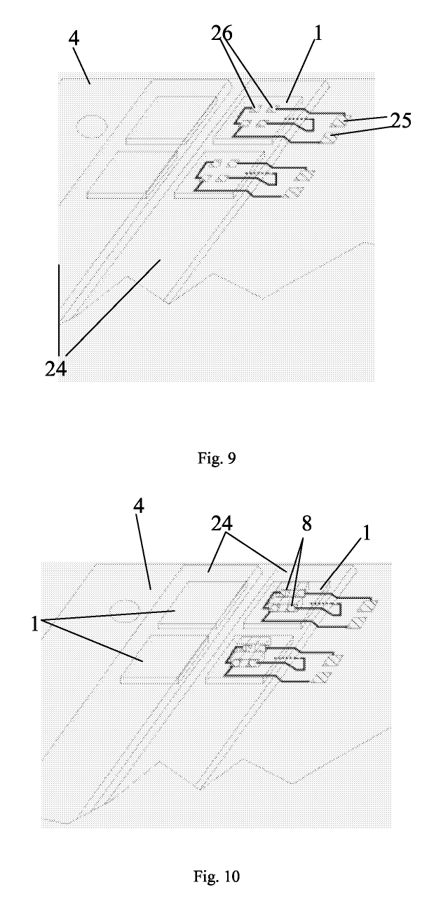

Following this step, metal traces 6 are formed on the encapsulation material 2 and as shown in the example of FIG. 9 and in FIGS. 1-6 connection leads 6 are generated between pads 25 on the PCB 4 and pads 26 on surface parts of the encapsulation material 2.

The entire PCB board 4 is then run through a pick and place automat wherein electric components 8 are mounted on the pads 26 on the encapsulation surface. Hereafter the PCB is run through a soldering tunnel, causing the components to be fastened to the surface and electrically connected to the pads. The resulting array of devices with the mounted components is seen in FIG. 10.

The audio devices are then singularized, preferably by sawing the PCB, whereafter they are ready for use in hearing aids or other audio processing equipment. In the description above each device contain only one chip, but multi chip devices are easily provided by chip-on-chip mounting or by mounting chips side by side on the same PCB.

Two ways of generating the metal on top of the encapsulation material is described in more detail in the following. The first way comprises electrochemical deposition of metal in traces or covering larger surfaces. Here the surface of the chip encapsulation material is activated to provide catalytic sites for the metal deposition. The activation results in inclusion of precious metal ions (Pd, Pt, Au, etc.) in the surface of the encapsulation. The inclusion of the metal ions in the surface is obtained either by photochemical dissociation of an organic metal complex, which has been added to the encapsulation material and which contains the precious metal, or by sequentially treating the surface in dedicated micro-etch, pre-activator and activator solutions. Here the later provides the precious metal ions. In the photochemical dissociation the organic metal complex in the chip encapsulation material is cracked open by a focused laser beam and the metal atoms are broken off from organic ligands. The metal atoms then act as nuclei for reduction of metal ions during a subsequent electrochemical deposition process. The laser activation is performed in traces to provide electric connection to discrete components as disclosed above or along larger areas to allow protective layers of metal to be formed on selected areas.

After surface activation metal is electrochemically deposited either by electroless plating or by electroplating. In situations where the electrochemically deposited metal is not allowed to be deposited elsewhere on the PCB, the metallic pads for wirebonding, solder bump bonding, etc. must be protected/masked during metal deposition. This is done by covering the pads with a layer of polyimide, which is later ablated by a laser in order to re-open the pads.

A second way of providing metal layers on the encapsulation material is Maskless Mesoscale Materials Deposition, also known as M3D technology. This process is promoted by Optomec, www.optomec.com. Here aerodynamic focusing is used in a maskless deposition of chemical precursor solutions and colloidal suspensions. An aerosol stream is focused, deposited, and patterned onto the surface of the encapsulation material. Also un-even surfaces with cavities as disclosed above are provided with metal layering. A thermal annealing or photochemical (laser decomposition) process to achieve physical and/or electrical properties near that of the bulk material follows the deposition.

1. Audio processing device with at least one encapsulated electronic component mounted and electrically connected to electric leads in a mounting substrate and where further electric components are mounted for connection with the encapsulated electronic component through the substrate and where the encapsulation material is moulded onto the substrate whereby at least one metal layer is deposited on a surface part of the encapsulation material.

2. Audio device as claimed in claim 1, wherein the at least one encapsulated electronic component comprises at least on semiconductor chip.

3. Audio processing device as claimed in claim 1, wherein the metal layer on the encapsulation material is provided as conductive metal traces which are electrically connected with the leads in the mounting substrate and whereby electric components are formed on or mounted onto the surface of the encapsulation material and connected with the leads in the substrate through the metal traces.

4. Audio processing device as claimed in claim 1 whereby the metal layers or traces form capacitors, coils, antennas or other active or passive devices on the encapsulation material.

5. Audio processing device as claimed in claim 1, whereby the encapsulation material comprises cavities or other surface structures, serving as part of, or receiving means for a component.

6. Method for producing an amplifier for an audio device whereby at least one electronic component is mounted on and electrically connected to a PCB and where an encapsulation material is provided to protect the at least one electronic component, wherein further a metal layer is generated at least on a surface area of the encapsulation material.

7. Method as claimed in claim 6, wherein the surface of the electronic component encapsulation material is provided with cavities or other surface structures during moulding of the encapsulation material onto the PCB.

8. Method as claimed in claim 6, whereby an acoustic transducer part is mounted onto a cavity structure of the encapsulation material and gains contact with other electric components through the electric lead on the surface of the encapsulation material.

9. Method as claimed in claim 6, wherein the metal layer is deposited by an electrochemical deposition method.

10. Method as claimed in claim 6, wherein the metal layer is deposited through a nozzle directly onto the surface of the chip encapsulation material.
